(19) United States
(12) Patent Application Publication
(10) Pub. No.: US 2026/0090011 A1
(43) Pub. Date: Mar. 26, 2026

(54) SILICON CARBIDE SEMICONDUCTOR DEVICE

(71) Applicant: FUJI ELECTRIC CO., LTD., Kawasaki-shi (JP)

(72) Inventor: Yasuyuki HOSHI, Matsumoto-city (JP)

(73) Assignee: FUJI ELECTRIC CO., LTD., Kawasaki-shi (JP)

(21) Appl. No.: 19/284,882

(22) Filed: Jul. 30, 2025

(30) Foreign Application Priority Data
Sep. 26, 2024 (JP) 2024-167179

(51) Int. Cl. H10D 30/66; H01L 21/265; H10D 62/40; H10D 62/60; H10D 62/832; H10D 64/23; H10D 64/62

(52) U.S. Cl. CPC H10D 30/668; H10D 62/60; H10D 64/2527; H10D 64/62; H10P 30/222; H10D 62/40; H10D 62/8325

(57) ABSTRACT

The SiC semiconductor device includes: a semiconductor substrate containing SiC; an insulated gate electrode structure buried in a first trench 8 provided in the semiconductor substrate; a trench contact 12 buried in a second trench 11 provided in the semiconductor substrate; a second conductivity type base region provided in contact with a side surface of the first trench and a side surface of the second trench in the semiconductor substrate; a first conductivity type main electrode region provided in contact with the side surface of the first trench and the side surface of the second trench on an upper surface side of the base region; and a second conductivity type base contact region provided in contact with a bottom surface of the second trench, in which a region along the side surface and the bottom surface of the second trench in the semiconductor substrate contains 3H-SiC.

### CROSS-REFERENCE TO RELATED APPLICATION

This application claims benefit of priority under 35 USC 119 based on Japanese Patent Application No. 2024-167179 filed on Sep. 26, 2024, the entire contents of which are incorporated by reference herein.

### BACKGROUND OF THE INVENTION

### 1. Field of the Invention

The present disclosure relates to a silicon carbide semiconductor device.

### 2. Description of the Related Art

JP 2009-049198 A discloses a semiconductor device where phosphorus ions are implanted into a hexagonal single crystal silicon carbide substrate to form an amorphous layer, a heat treatment is performed on the amorphous layer to recrystallize the amorphous layer into cubic single crystal n-type silicon carbide, and nickel is deposited on an upper surface of the n-type silicon carbide to form an electrode.

WO 2017/042963 A1 discloses a semiconductor device that, in an n⁻ type epitaxially-grown layer where that is formed on an n⁺ type SiC first primary surface formed of 4H-SiC, an n⁺ type source region, an n⁺ type 3H-SiC region formed in the n⁺ type source region, and a p⁺ type potential fixing region are provided, a barrier metal film is formed in contact with the n⁺ type 3H-SiC region and the p⁺ type potential fixing region, and a source wiring electrode is formed on the barrier metal film.

When a pitch (cell pitch) of a plurality of active elements arranged in parallel is reduced, a contact area between a main electrode and a semiconductor layer is reduced, and a contact resistance increases. This way, the contact resistance may affect miniaturization of the semiconductor device.

### SUMMARY OF INVENTION

An object of the present disclosure is to provide a silicon carbide semiconductor device where a contact resistance can be suppressed.

To achieve the above-described object, the summary of one aspect of the present disclosure is a silicon carbide semiconductor device including: (a) a semiconductor substrate containing silicon carbide; (b) an insulated gate electrode structure that is buried in a first trench provided in the semiconductor substrate; (c) a trench contact that is buried in a second trench provided in the semiconductor substrate; (d) a second conductivity type base region that is provided in contact with a side surface of the first trench and a side surface of the second trench in the semiconductor substrate; (e) a first conductivity type main electrode region that is provided in contact with the side surface of the first trench and the side surface of the second trench on an upper surface side of the base region; and (f) a second conductivity type base contact region that is provided in contact with a bottom surface of the second trench, (g) in which a region along the side surface and the bottom surface of the second trench in the semiconductor substrate contains silicon carbide having a 3C structure.

### BRIEF DESCRIPTION OF DRAWINGS

FIG. 1 is a cross-sectional view in a vertical direction illustrating an example of an active element in a SiC semiconductor device according to a first embodiment;

FIG. 2 is an enlarged cross-sectional view illustrating a region A of FIG. 1;

FIG. 3 is an explanatory diagram illustrating a positional relationship in a plan view illustrating a gate trench, a contact trench, and an interlayer insulating film according to the first embodiment;

FIG. 4 is a process cross-sectional view illustrating an example of a method of manufacturing the SiC semiconductor device according to the first embodiment;

FIG. 5 is a process cross-sectional view illustrating the example of the method of manufacturing the SiC semiconductor device according to the first embodiment;

FIG. 6 is a process cross-sectional view illustrating the example of the method of manufacturing the SiC semiconductor device according to the first embodiment;

FIG. 7 is a process cross-sectional view illustrating the example of the method of manufacturing the SiC semiconductor device according to the first embodiment;

FIG. 8 is a process cross-sectional view illustrating the example of the method of manufacturing the SiC semiconductor device according to the first embodiment;

FIG. 9 is a process cross-sectional view illustrating the example of the method of manufacturing the SiC semiconductor device according to the first embodiment; and

FIG. 10 is a cross-sectional view in a vertical direction illustrating an example of a contact trench in a SiC semiconductor device according to a first modification example of the first embodiment.

### DETAILED DESCRIPTION

Hereinafter, embodiments of the present disclosure will be described with reference to the drawings. In the description of the drawings, the same or similar parts will be given the same or similar reference numerals and repeated descriptions will be omitted. Here, the drawings are schematic, and a relationship between a thickness and a plane dimension, a ratio of a thickness of each layer, and the like may be different from actual ones. Some parts may have different relationship in size and different ratio among the drawings. In addition, the embodiments described below exemplify devices and methods for embodying the technical idea of the present disclosure, and the technical idea of the present disclosure does not specify the material, shape, structure, arrangement, and the like of the components in the following embodiments.

In the present specification, “first main electrode region” refers to a semiconductor region that is one of a source region and a drain region in a field effect transistor (FET) or a static induction transistor (SIT). In an insulated gate bipolar transistor (IGBT), “first main electrode region” refers to a semiconductor region that is one of an emitter region and a collector region. Alternatively, in a static induction thyristor (SI thyristor) or a gate turn-off thyristor (GTO), “first main electrode region” refers to a semiconductor region that is one of an anode region and a cathode region. “Second main electrode region” refers to a semiconductor region that is the other one of the source region and the drain region in the FET or the SIT. In the IGBT, “second main electrode region” refers to a region that is the other one of the emitter region and the collector region. In the SI thyristor or the GTO, “second main electrode region” refers to a semiconductor region that is the other one of the anode region and the cathode region. This way, when “first main electrode region” is the source region, “second main electrode region” is the drain region. When “first main electrode region” is the emitter region, “second main electrode region” is the collector region. When “first main electrode region” is the anode region, “second main electrode region” is the cathode region. When a bias relationship is replaced, in the FET or the like, a function of “first main electrode region” and a function of “second main electrode region” can be replaced. Further, in the present specification, when “main electrode region” is simply described, “main electrode region” comprehensively refers to one of the first main electrode region and the second main electrode region.

In addition, in the following description, the definitions of directions such as an up-down direction are merely definitions for convenience of description, and do not limit the technical idea of the present disclosure. For example, of course, when an object is rotated by 90° and observed, the upper and lower sides are replaced with the right and left sides, and when an object is rotated by 180° and observed, the upper and lower sides are inverted. In addition, “upper surface” may be replaced with “front surface”, and “lower surface” may be replaced with “back surface”.

In addition, in the following description, an example where a first conductivity type is an n-type and a second conductivity type is a p-type will be described. However, the conductivity types may be selected to have the opposite relationship such that the first conductivity type is the p-type and the second conductivity type the n-type. In addition, “+” or “−” added to “n” or “p” represents a semiconductor region having a relatively higher or lower impurity concentration compared to a semiconductor region to which “+” and “−” are not added. Note that even in semiconductor regions to which “n” and “n” are added, respectively, impurity concentrations in the semiconductor regions are not strictly the same. Further, in the following description, it is technically and logically obvious that a member or region to which a limitation of “first conductivity type” or “second conductivity type” is added refers to a member or region formed of a semiconductor material without being clearly stated.

In addition, in SiC crystal, crystalline polymorphs are present, and primary polymorphs are cubic 3C and hexagonal 4H and 6H. As a bandgap at room temperature, a value of 2.23 eV is reported in the 3C-SiC, a value of 3.26 eV is reported in the 4H-SiC, and a value of 3.02 eV is reported in the 6H-SiC. In the following description, an example where 4H-SiC and 3C-SiC are mainly used will be described.

### First Embodiment

### Structure of SiC Semiconductor Device

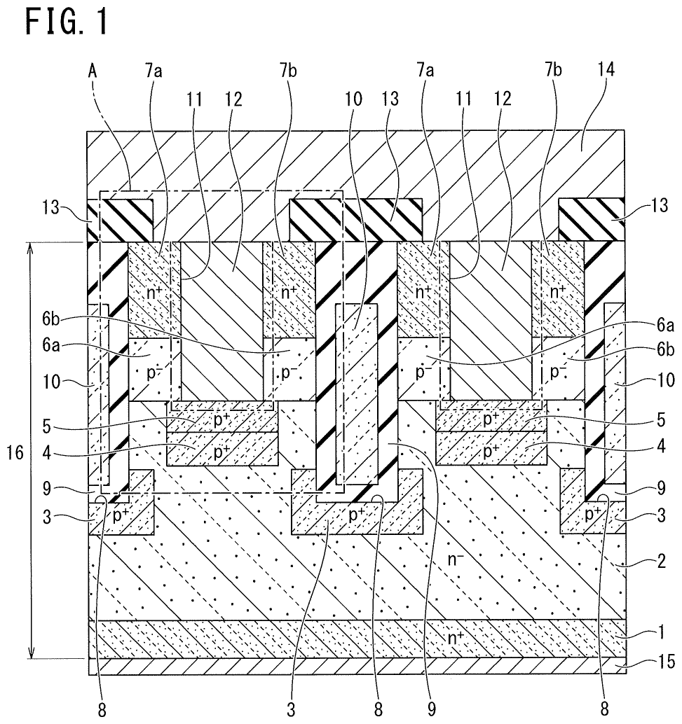

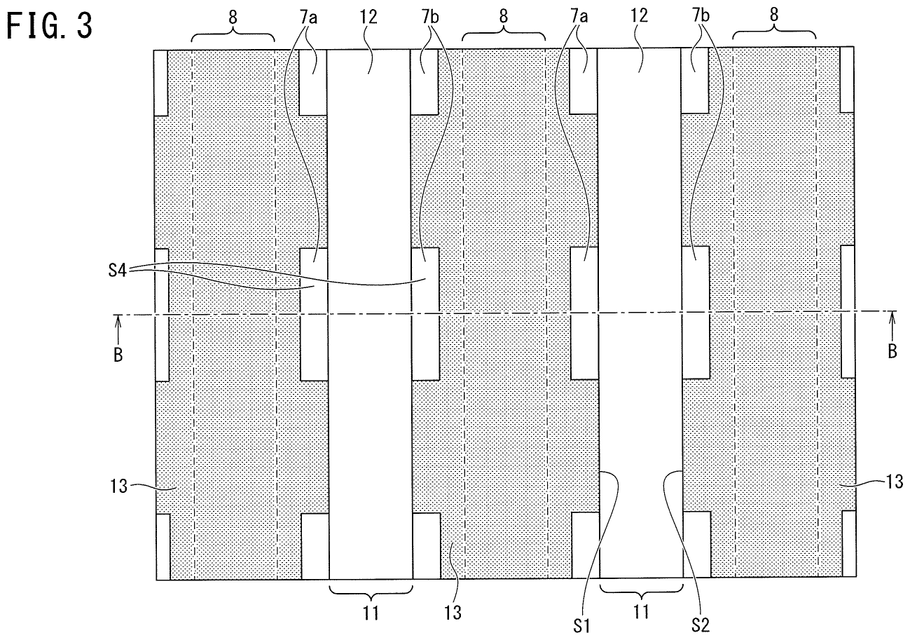

As a silicon carbide semiconductor device (SiC semiconductor device) according to a first embodiment, a trench gate MOSFET will be described as an example. FIG. 1 illustrates a cross-section in a vertical direction when seen from a B-B direction of FIG. 3.

As illustrated in FIG. 1, the SiC semiconductor device according to the first embodiment includes a semiconductor substrate 16. The semiconductor substrate 16 is formed of, for example, a silicon carbide (SiC) substrate.

The semiconductor substrate 16 includes a first conductivity type (n⁻ type) drift layer 2. Second conductivity type (p⁻ type) base regions 6a and 6b are provided on an upper surface side of the drift layer 2. Lower surfaces of the base regions 6a and 6b are in contact with the upper surface of the drift layer 2. On an upper surface side of the base regions 6a and 6b, first conductivity type (n⁺ type) first main electrode regions (source regions) 7a and 7b are provided.

The upper surfaces of the base regions 6a and 6b are in contact with the lower surfaces of the source regions 7a and 7b. The impurity concentration in the source regions 7a and 7b is higher than the impurity concentration in the drift layer 2.

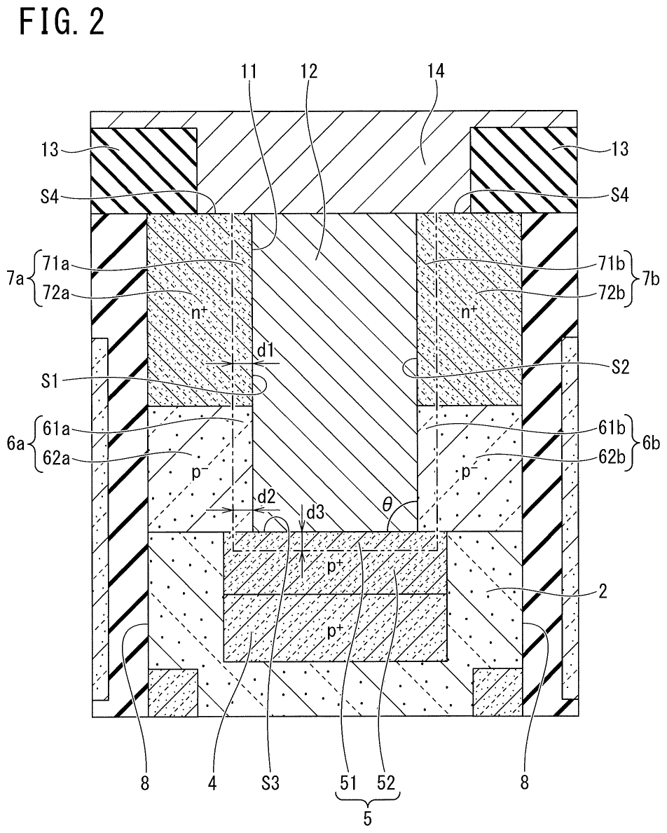

On an upper surface side of the semiconductor substrate 16, a plurality of trenches (gate trenches) 8 are arranged to be spaced from each other. The plurality of gate trenches 8 have the same width and the same depth. The gate trench 8 is a first trench that is provided in a depth direction that is a direction perpendicular to the upper surface of the semiconductor substrate 16 from the upper surface of the semiconductor substrate 16. The gate trench 8 penetrates the source regions 7a and 7b and the base regions 6a and 6b and reaches the drift layer 2. As illustrated in FIGS. 1 and 2, side surfaces of the source regions 7a and 7b, the base regions 6a and 6b, and the drift layer 2 are in contact with side surface (side wall) of the gate trench 8. As illustrated in FIG. 1, a gate bottom protection region 3 is provided in a bottom portion of the gate trench 8. The gate bottom protection region 3 is a second conductivity type (p⁺ type) semiconductor region having a higher impurity concentration than the base regions 6a and 6b, and is provided inside the drift layer 2.

A gate insulating film 9 is provided to cover a bottom surface (lower surface) and a side surface of the gate trench 8. As the gate insulating film 9, for example, a single-layer film of any one selected from a silicon dioxide film (SiO₂ film), a silicon oxynitride (SiON) film, a strontium oxide (SrO) film, a silicon nitride (Si₃N₄) film, an aluminum oxide (Al₂O₃) film, a magnesium oxide (MgO) film, a yttrium oxide (Y₂O₃) film, a hafnium oxide (HfO₂) film, a zirconium oxide (ZrO₂) film, a tantalum oxide (Ta₂O₅) film, and a bismuth oxide (Bi₂O₃) film, or a stacked-layer film where a plurality of films selected from the above films are stacked can be adopted.

In the gate trench 8, a gate insulating film 9 is interposed, and a gate electrode 10 is buried. The gate insulating film 9 and the gate electrode 10 form an insulated gate electrode structure (9, 10). As a material of the gate electrode 10, for example, a polysilicon film (doped polysilicon film) to which an impurity such as phosphorus (P) or boron (B) is added with a high impurity concentration can be used.

Among a plurality of insulated gate electrode structures (9, 10), some insulated gate electrode structures (9, 10) may be gate trench portions connected to a gate runner, and the remaining insulated gate electrode structures (9, 10) may be dummy trench portions that are not connected to the gate runner.

A mesa portion forming the upper portion of the semiconductor substrate 16 is provided between the gate trenches 8 adjacent to each other. The mesa portion is a region of the semiconductor substrate 16 interposed between the gate trench 8 adjacent to each other, and is a region over the deepest position of the gate trench 8. The mesa portions between the plurality of gate trenches 8 have the same width. The mesa portion includes an upper portion of the drift layer 2, a buried region 4, a base contact region 5, the base regions 6a and 6b, and the source regions 7a and 7b.

A trench (contact trench) 11 is provided in the mesa portion of the semiconductor substrate 16. The contact trench 11 is a second trench that is provided in the depth direction that is a direction perpendicular to the upper surface of the mesa portion from the upper surface of the mesa portion of the semiconductor substrate 16. As illustrated in FIG. 2, a cross-sectional shape of the contact trench 11 is rectangular, and an angle θ formed between a side surface S2 and a bottom surface S3 is, for example, about 90°. An angle formed between a side surface S1 and the bottom surface S3 is also about 90°. As illustrated in FIG. 1, a depth of the contact trench 11 is smaller than that of the gate trench 8. In addition, a width of the contact trench 11 is about 0.1 μm or more and 2 μm or less.

The contact trench 11 penetrates the source regions 7a and 7b and the base regions 6a and 6b and reaches the base contact region 5. The bottom surface S3 of the contact trench 11 may be at a depth position that is the same as or slightly lower than the lower surfaces of the base regions 6a and 6b.

The base contact region 5 is a second conductivity type (p⁺ type) semiconductor region having a higher impurity concentration than the base regions 6a and 6b. As illustrated in FIG. 2, the side surfaces of the source regions 7a and 7b and the base regions 6a and 6b are in contact with the side surfaces S1 and S2 (side wall surfaces) of the contact trench 11. The base contact region 5 is in contact with the bottom surface S3 (lower surface) of the contact trench 11. In a left-right direction of FIG. 2, a width of the base contact region 5 is provided to be wider than a width of the bottom surface S3 of the contact trench 11. In the base contact region 5, an upper surface of a portion not in contact with the bottom surface S3 is in contact with the lower surfaces of the base regions 6a and 6b. In the semiconductor substrate 16, a region along the side surfaces S1 and S2 and the bottom surface S3 of the contact trench 11 contains silicon carbide having a 3C structure.

As illustrated in FIG. 1, the second conductivity type (p⁺ type) buried region 4 having a lower impurity concentration than the base contact region 5 is provided on a lower surface side of the base contact region 5. An upper surface of the buried region 4 is in contact with the lower surface of the base contact region 5. A side surface of the base contact region 5 and a side surface and a lower surface of the buried region 4 are in contact with the drift layer 2.

The gate trench 8 may have a plane pattern extending in a stripe shape in a depth direction and a front direction of the paper plane in FIG. 1 or may be a dot-like plane pattern. The contact trench 11 is provided between two gate trenches 8 adjacent to each other. FIG. 3 illustrates the gate trenches 8 extending in a stripe shape. The contact trench 11 is provided to be spaced from the gate trench 8. The gate trenches 8 and the contact trenches 11 are alternately arranged in a stripe shape in the left-right direction of FIG. 3. The numbers of the gate trenches 8 and the contact trenches 11 are not limited to those of FIG. 3. The SiC semiconductor device according to the first embodiment has a multi-channel structure where a plurality of unit cells including the gate trench 8 are arranged, and can be a power semiconductor device (power device) for allowing a large current to flow.

As illustrated in FIG. 1, a conductor portion (trench contact) 12 is buried in the contact trench 11. The conductor portion 12 is formed of, for example, a metal material. The conductor portion 12 mainly contains, for example, tungsten (W) or aluminum (Al).

An interlayer insulating film 13 is selectively provided on the upper surface side of the insulated gate electrode structure (9, 10). The interlayer insulating film 13 is formed of, for example, a single-layer film such as a silicon oxide film to which boron (B) and phosphorus (P) are added (BPSG film), a silicon oxide film film to which phosphorus (P) is added (PSG), a non-doped silicon oxide film not containing phosphorus (P) or boron (B) that is called “NSG”, a silicon oxide film to which boron (B) is added (BSG film), or a silicon nitride film (Si₃N₄ film) or a stacked-layer film where a plurality of films selected from the above films are stacked. As illustrated in FIG. 3, an edge portion of the interlayer insulating film 13 in a plan view has unevenness.

For example, a projecting edge portion completely covers the source regions 7a and 7b, a recessed edge portion does not completely cover the source regions 7a and 7b, and a part of upper surfaces of the source regions 7a and 7b is exposed.

As illustrated in FIG. 1, a first main electrode (source electrode) 14 is provided to cover upper surfaces of the source regions 7a and 7b and the conductor portion 12 exposed between the interlayer insulating films 13. A lower surface of the source electrode 14 comes into contact with the upper surfaces of the source regions 7a and 7b and the conductor portion 12 to be electrically connected. The source electrode 14 is provided to be separated from a gate wiring electrode (not illustrated) electrically connected to the gate electrode 10. The source electrode 14 may have a stacked structure of a barrier metal layer as a lower layer and a source wiring electrode as an upper layer. The barrier metal layer is formed of metal, for example, titanium nitride (TiN), titanium (Ti), or a stacked structure of TiN/Ti where Ti forms a lower layer. The source wiring electrode is formed of metal, for example, aluminum (Al), aluminum-silicon (Al-Si), aluminum-copper (Al-Cu), or copper (Cu). The above-described conductor portion 12 and the source electrode 14 may be integrally formed of the same material.

On the lower surface side of the drift layer 2, a first conductivity type (n⁺ type) second main electrode region (drain region) 1 having a higher impurity concentration than the drift layer 2 is provided. The drain region 1 is formed of a semiconductor substrate (SiC substrate) formed of SiC. A dislocation conversion layer or a recombination promotion layer that is an n-type buffer layer having an impurity concentration that is higher than that of the drift layer 2 and lower than that of the drain region 1 may be provided between the drift layer 2 and the drain region 1.

A second main electrode (drain electrode) 15 is provided on a lower surface side of the drain region 1. As the drain electrode 15, for example, a single-layer film formed of gold (Au) or a metal film where titanium (Ti), nickel (Ni), and Au are stacked in this order from the drain region 1 side can be used. Further, a metal film of molybdenum (Mo), tungsten (W), or the like may be stacked on the lowermost layer. In addition, a drain contact layer such as a nickel silicide (NiSiₓ) film for ohmic contact may be provided between the drain region 1 and the drain electrode 15. When “main electrode” is simply described, “main electrode” comprehensively refers to any one of the first main electrode (source electrode) 14 and the second main electrode (drain electrode) 15.

FIG. 2 is an enlarged view illustrating a region A of a dash-dotted line surrounding the periphery of the contact trench 11 of FIG. 1. In the source region 7a, a region along the side surface S1 of the contact trench 11 will be referred to as a first source region 71a, and a region other than the first source region 71a will be referred to as a second source region 72a. In the source region 7b, a region along the side surface S2 of the contact trench 11 will be referred to as a first source region 71b, and a region other than the first source region 71b will be referred to as a second source region 72b. One side surface of the first source regions 71a and 71b is in contact with the side surfaces S1 and S2 of the contact trench 11, and the other side surface thereof is in contact with one side surface of the second source regions 72a and 72b. The other side surface of the second source regions 72a and 72b is in contact with the gate trench 8.

In the base region 6a, a region along the side surface S1 of the contact trench 11 will be referred to as a first base region 61a, and a region other than the first base region 61a will be referred to as a second base region 62a. In the base region 6b, a region along the side surface S2 of the contact trench 11 will be referred to as a first base region 61b, and a region other than the first base region 61b will be referred to as a second base region 62b. One side surface of the first base regions 61a and 61b is in contact with the side surfaces S1 and S2 of the contact trench 11, and the other side surface thereof is in contact with one side surface of the second base regions 62a and 62b. The other side surface of the second base regions 62a and 62b is in contact with the gate trench 8.

In the base contact region 5, a region along the bottom surface S3 of the contact trench 11 will be referred to as a first base contact region 51, and a region other than the first base contact region 51 will be referred to as a second base contact region 52. An upper surface of the first base contact region 51 is in contact with the bottom surface S3 of the contact trench 11, and a lower surface thereof is in contact with an upper surface of the second base contact region 52.

The first source regions 71a and 71b, the first base regions 61a and 61b, and the first base contact region 51 are regions containing 3H-SiC (3C structure). The first source regions 71a and 71b, the first base regions 61a and 61b, and the first base contact region 51 may be mixed crystal of 3H-SiC and 4H-SiC (4C structure). The first source regions 71a and 71b, the first base regions 61a and 61b, and the first base contact region 51 may contain an amorphous structure, 4H-SiC, or the like other than 3H-SiC. The 3H-SiC has a narrower bandgap than the 4H-SiC. Therefore, by containing the 3H-SiC, the first source regions 71a and 71b, the first base regions 61a and 61b, and the first base contact region 51 can be made to be in ohmic contact with the conductor portion 12. In addition, since containing the 3H-SiC, even if the first source regions 71a and 71b, the first base regions 61a and 61b, and the first base contact region 51 are made to be in direct contact with the conductor portion 12, the contact resistance can be suppressed. Therefore, a silicide film does not need to be provided. When the first source regions 71a and 71b, the first base regions 61a and 61b, and the first base contact region 51 contain 3H-SiC, the contact resistance with the conductor portion 12 can be suppressed. A proportion of the 3C-SiC in the first source regions 71a and 71b, the first base regions 61a and 61b, and the first base contact region 51 may be, for example, about 10% or more and 100% or less although not limited thereto. For example, by setting the proportion of the 3C-SiC in the first source regions 71a and 71b, the first base regions 61a and 61b, and the first base contact region 51 to be 10% or more, more favorable ohmic contact with the conductor portion 12 can be realized.

A thickness d1 between one side surface and the other side surface of the first source regions 71a and 71b, a thickness d2 between one side surface and the other side surface of the first base regions 61a and 61b, and a thickness d3 between the upper surface and the lower surface of the first base contact region 51 are, for example, about 20 nm or more and 100 nm or less. The thicknesses d1, d2, and d3 may be the same as or different from each other.

A concentration of n-type impurity in the first source regions 71a and 71b is higher than an impurity concentration in the second source regions 72a and 72b. The impurity concentration in the first source regions 71a and 71b is, for example, about 1×10¹⁸ cm⁻³ or more and 7×10¹⁹ cm⁻³ or less.

The first source regions 71a and 71b contains, for example, phosphorus (P) or nitrogen (N) as the n-type impurity. The first source regions 71a and 71b may contain, for example, arsenic (As) as the n-type impurity. The first source regions 71a and 71b may contain plural kinds of impurities among known n-type impurities such as P, As, or N as the n-type impurity.

A concentration of p-type impurity in the first base regions 61a and 61b is higher than an impurity concentration in the second base regions 62a and 62b. The impurity concentration in the first base regions 61a and 61b is, for example, about 1×10¹⁸ cm⁻³ or more and 2×10²⁰ cm⁻³ or less.

The first base regions 61a and 61b may contain, for example, aluminum (Al) as the p-type impurity. The first base regions 61a and 61b may contain, for example, boron (B) as the p-type impurity. The first base regions 61a and 61b may contain plural kinds of impurities among known p-type impurities such as Al or B as the p-type impurity.

A concentration of p-type impurity in the first base contact region 51 is higher than an impurity concentration in the second base contact region 52. The impurity concentration in the second base contact region 52 is, for example, about 1×10¹⁸ cm⁻³ or more and 2×10²⁰ cm⁻³ or less. The first base contact region 51 may contain, for example, aluminum (Al) as the p-type impurity. The first base contact region 51 may contain, for example, boron (B) as the p-type impurity. The first base contact region 51 may contain plural kinds of impurities among known p-type impurities such as Al or B as the p-type impurity.

The second source regions 72a and 72b, the second base regions 62a and 62b, and the second base contact region 52 are mainly formed of 4H-SiC (4C structure). A proportion of the 4H-SiC in the second source regions 72a and 72b, the second base regions 62a and 62b, and the second base contact region 52 may be, for example, about 90% or more and 100% or less.

The second source regions 72a and 72b, the second base regions 62a and 62b, and the second base contact region 52 may slightly contain an amorphous structure, 3C-SiC, or the like other than 4H-SiC.

The second source regions 72a and 72b contain, for example, phosphorus (P) or nitrogen (N) as the n-type impurity. The second source regions 72a and 72b may contain arsenic (As) as the n-type impurity. The second base regions 62a and 62b and the second base contact region 52 may contain, for example, aluminum (Al) or boron (B) as the p-type impurity.

During an operation of the SiC semiconductor device according to the first embodiment, the source electrode 14 is set at a ground potential and a positive voltage is applied to the drain electrode 15, and when a positive voltage of a threshold or higher is applied to the gate electrode 10, an inversion layer (channel) is formed on a side surface side of the gate trench 8 of the base regions 6a and 6b such that an ON state is established. In the ON state, a current flows from the drain electrode 15 to the source electrode 14 through the drain region 1, the drift layer 2, the inversion layer of the base regions 6a and 6b, and the source regions 7a and 7b. On the other hand, when a voltage to be applied to the gate electrode 10 is less than a threshold, the inversion layer is not formed in the base regions 6a and 6b. Therefore, the OFF state is established, and a current does not flow from the drain electrode 15 to the source electrode 14.

### Method of Manufacturing SiC Semiconductor Device

Next, an example of a method of manufacturing the SiC semiconductor device according to the first embodiment will be described. More specifically, a method of forming the first source regions 71a and 71b, the first base regions 61a and 61b, and the first base contact region 51 will be mainly described. The method of manufacturing the SiC semiconductor device described below is an example and, of course, can be realized by various other manufacturing methods including modification examples thereof within the scope described in the claims.

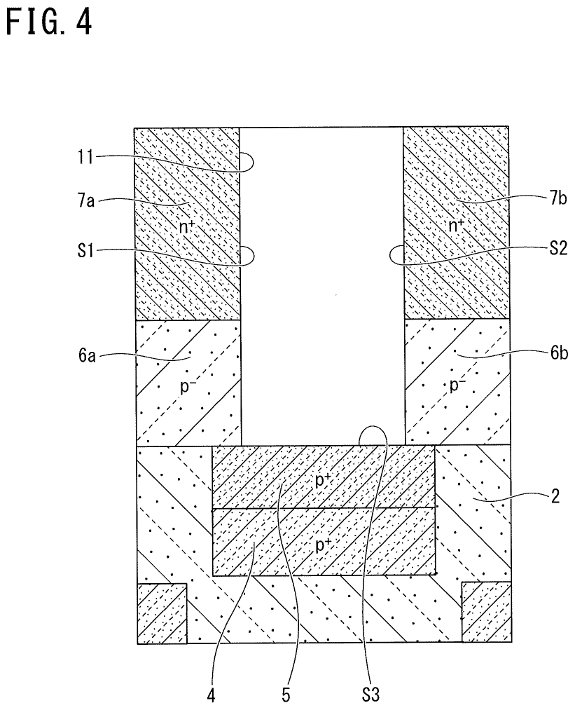

Selective formation of 4H-SiC and 3C-SiC can be realized by changing an element of which ions are to be implanted, a temperature during the ion implantation, a dose (impurity concentration), and an activation temperature, and the like for each region. A process cross-sectional view illustrated in FIG. 4 illustrates the drift layer 2, the base regions 6a and 6b, the source regions 7a and 7b, the buried region 4, and the base contact region 5 mainly formed of 4H-SiC before formation of 3C-SiC. After forming these semiconductor regions, the contact trench 11 is formed. As a method of forming the base regions 6a and 6b, the source regions 7a and 7b, the buried region 4, and the base contact region 5, ions of n-type impurity or p-type impurity are implanted into the 4H-SiC at a high temperature (for example, about 500° C.) with a concentration where the structure of the 4H-SiC does not collapse. As a result, the 4H-SiC is maintained, and the base regions 6a and 6b, the source regions 7a and 7b, the buried region 4, and the base contact region 5 are formed. In this state, the inside of the contact trench 11 illustrated in FIG. 4 is hollow, and the conductor portion 12 is not yet formed.

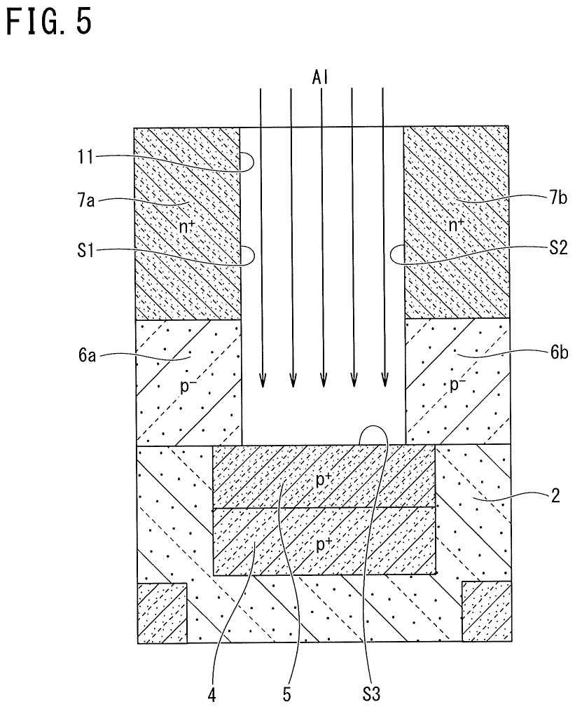

Hereinafter, conditions of processes illustrated in FIGS. 5 to 9 will be described. As a method of forming 3C-SiC, by implanting ions of n-type impurity (first conductivity type impurity) or p-type impurity (second conductivity type impurity) into 4H-SiC, the structure of 4H-SiC collapses to form an amorphous structure. The temperature during the ion implantation is set to be low for collapsing the structure of 4H-SiC. By performing the ion implantation of the impurity with a high concentration at a low temperature, the structure of 4H-SiC can be collapsed. The temperature during the ion implantation is set to be, for example, about room temperature (for example, 20° C.) or higher and 200° C. or lower. The dose (total dose) of each of the n-type impurity and the p-type impurity is set to be, for example, 1×10¹⁵ cm⁻² or more.

The ion implantation of the n-type impurity and the p-type impurity is selectively performed on the side surfaces S1 and S2 and the bottom surface S3 of the contact trench 11.

Ions of the n-type impurity are implanted into the n-type semiconductor region, and ions of the p-type impurity are implanted into the p-type semiconductor region. The ion implantation is mainly performed on a shallow position in the vicinity of the side surfaces S1 and S2 and the bottom surface S3. As a result, an amorphous structure can be formed in the vicinity of the side surfaces S1 and S2 and the bottom surface S3 of the contact trench 11.

First, ions of the p-type impurity (for example, Al) are implanted into the base regions 6a and 6b and the base contact region 5. As a method of the ion implantation, the following three methods including Examples 1 to 3 can be used.

### Example 1

As illustrated in FIG. 5, ions of Al are vertically implanted into the bottom surface S3 of the contact trench 11.

### Example 2

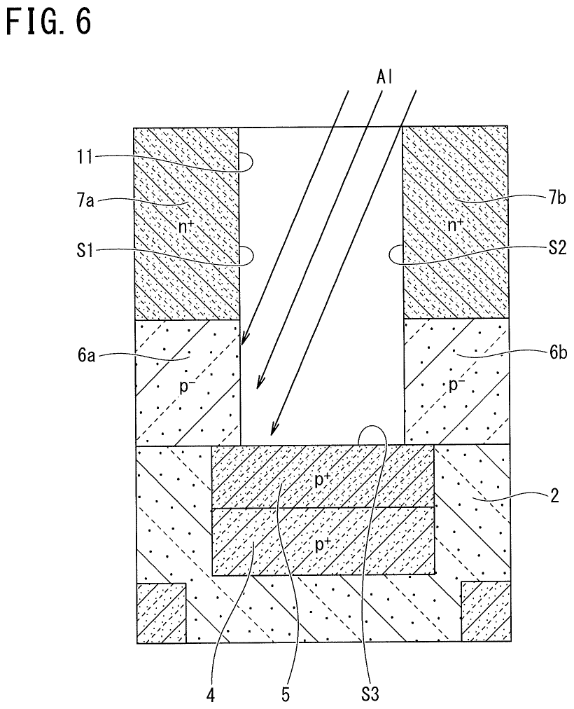

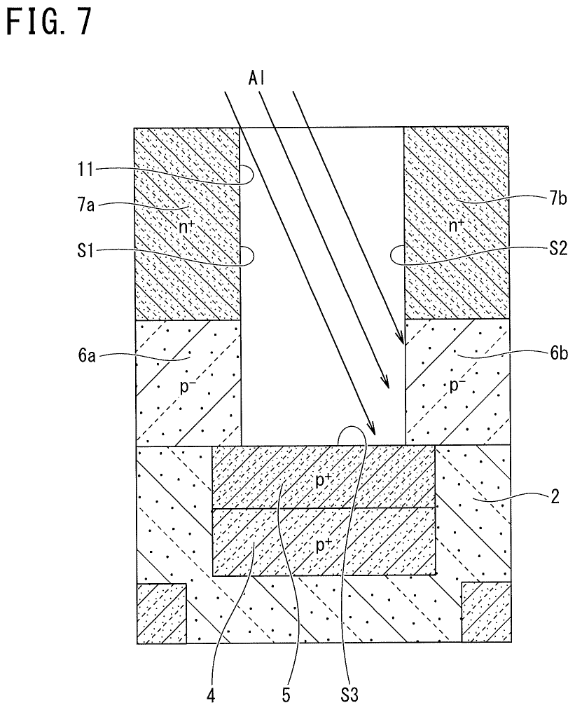

As illustrated in FIG. 6, ions of Al are obliquely implanted into the lower side of the side surface S1 of the contact trench 11. Next, as illustrated in FIG. 7, ions of Al are obliquely implanted into the lower side of the side surface S2 of the contact trench 11. After performing the ion implantation illustrated in FIG. 7, the ion implantation illustrated in FIG. 6 may be performed.

### Example 3

All of the ion implantations illustrated in FIGS. 5, 6, and 7 are performed.

After performing the ion implantation according to any one of Examples 1, 2, and 3, ions of the n-type impurity (for example, N) are implanted into the source regions 7a and 7b.

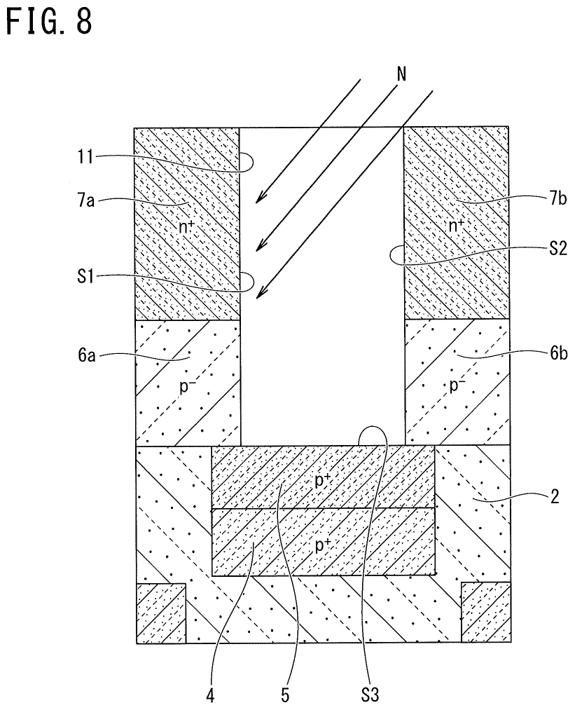

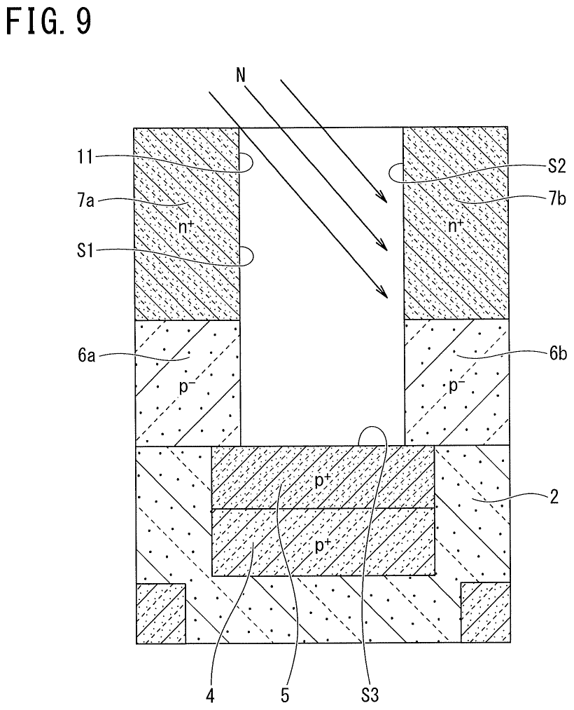

For example, as illustrated in FIG. 8, ions of N are obliquely implanted into the upper side of the side surface S1 of the contact trench 11. The angle of the ion implantation with respect to the vertical direction is more than that of FIG. 6 of Example 2. Likewise, as illustrated in FIG. 9, ions of N are obliquely implanted into the upper side of the side surface S2 of the contact trench 11. The angle of the ion implantation with respect to the vertical direction is more than that of FIG. 7 of Example 2. After performing the ion implantation illustrated in FIG. 9, the ion implantation illustrated in FIG. 8 may be performed.

Next, activation annealing is performed. A temperature of the activation annealing is, for example, about 1600° C. or higher and 1900° C. or lower. When the amorphous structure is recrystallized through the activation annealing, 3H-SiC is formed. As a result, the amorphous structure can be formed in the vicinity of the side surfaces S1 and S2 and the bottom surface S3 of the contact trench 11. As a result, the first source regions 71a and 71b, the first base regions 61a and 61b, and the first base contact region 51 containing 3H-SiC can be formed. Next, the conductor portion 12 is formed inside the contact trench 11. The description regarding the subsequent processes will be omitted.

The buried region 4 and the base contact region 5 may be formed through ion implantation after forming the contact trench 11. In addition, the ion implantation of the p-type impurity may be performed after performing the ion implantation of the n-type impurity.

### Main Effect of First Embodiment

Hereinafter, the main effect of the SiC semiconductor device according to the first embodiment will be described, and an overview will be described before describing the main effect. To further realize miniaturization of the unit cells, a technology of burying an electrode material in a trench provided in a SiC semiconductor substrate to form a trench contact has been studied. Even when the unit cells are miniaturized, a contact area between the SiC semiconductor substrate and a source electrode can be ensured by forming the trench contact. In addition, to realize ohmic contact between the SiC semiconductor substrate and the electrode, the electrode needs to be formed on a surface of the SiC semiconductor substrate after providing a silicide film such as nickel silicide (NiSiₓ). The same also applies to the case of the trench contact, and the electrode material needs to be buried in the trench after providing the silicide film on an inner surface of the trench. However, it is not easy to provide the silicide film inside the trench.

For example, it is not easy to uniformly form the silicide film on a vertical surface of the trench. A region where the silicide film is not formed on the vertical surface may be present. In addition, the silicide film may not be formed on a corner of the trench. When the region where the silicide film is not formed is present on the inner surface of the trench, a contact resistance between the SiC semiconductor substrate and the trench contact increases. This way, with the simple configuration of providing the trench contact, it is not easy to realize an ohmic junction between the trench contact and the SiC semiconductor substrate, and it is difficult to reduce the cell pitch.

On the other hand, in the SiC semiconductor device according to the first embodiment, in the semiconductor substrate 16, a region along the side surfaces S1 and S2 and the bottom surface S3 of the contact trench 11 contains silicon carbide having a 3C structure. More specifically, the first source regions 71a and 71b, the first base regions 61a and 61b, and the first base contact region 51 contain silicon carbide having a 3C structure. Since 3H-SiC has a smaller contact resistance than 4H-SiC, the semiconductor substrate 16 can come into ohmic contact with the conductor portion 12 with a low resistance without providing a silicide film.

Therefore, the contact resistance can be suppressed. As a result, the contact can be trenched, the cell pitch can be reduced, and miniaturization can be further realized. In addition, the reliability of the trench contact can be improved.

In the SiC semiconductor device according to the first embodiment, ions of the n-type impurity or the p-type impurity are implanted into the 4H-SiC exposed to the side surfaces S1 and S2 and the bottom surface S3 of the contact trench 11, and 3H-SiC is formed through the process of amorphization. Therefore, while suppressing the cost, the 3H-SiC can be easily and stably formed.

In the SiC semiconductor device according to the first embodiment, by providing 3H-SiC, unevenness of a junction surface between the conductor portion 12 and the SiC semiconductor substrate can be reduced compared to a case where a silicide film is provided. As a result, adhesiveness between the SiC semiconductor substrate and the conductor portion 12 can be improved.

### First Modification Example of First Embodiment

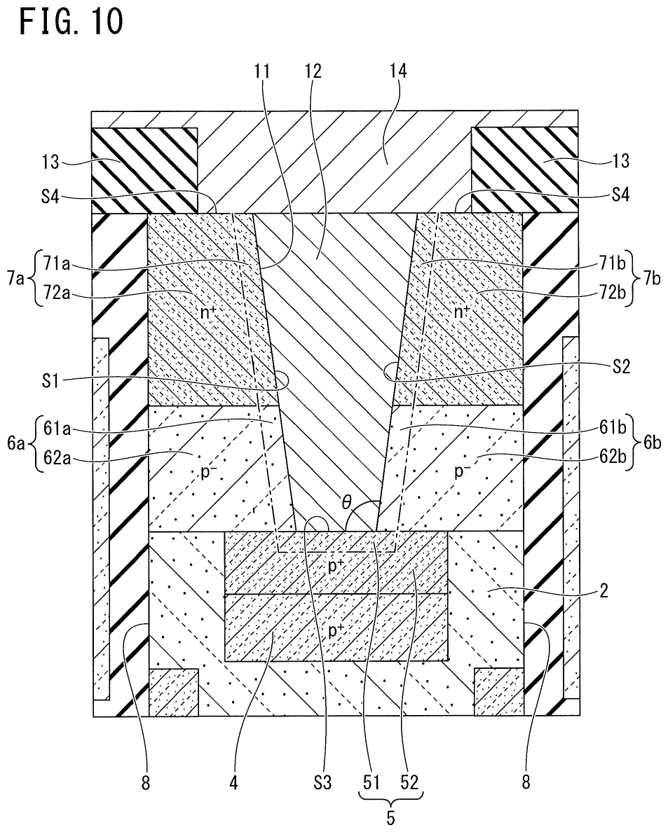

A SiC semiconductor device according to a first modification example of the first embodiment is different from the SiC semiconductor device according to the first embodiment, in that a cross-sectional shape of the contact trench 11 is a tapered shape (trapezoidal shape) as illustrated in FIG. 10. The other configurations of the semiconductor device according to the first modification example of the first embodiment are the same as those of the SiC semiconductor device according to the first embodiment, and thus the repeated description will not be made.

The side surface of the contact trench 11 has, for example, a forward tapered shape of being narrowed from an opening portion toward the bottom surface S3. The angle θ formed between the side surface S2 and the bottom surface S3 of the contact trench 11 is, for example, more than 90°. The angle formed between the side surface S1 and the bottom surface S3 is also about 90°. By setting the cross-sectional shape of the contact trench 11 to be the tapered shape, ions of the impurity are easily implanted into the side surfaces S1 and S2 of the contact trench 11. As a result, 3H-SiC can be more stably formed on the side surfaces S1 and S2 and the bottom surface S3 of the contact trench 11. In addition, by setting the cross-sectional shape of the contact trench 11 to be the tapered shape, the contact area between the first source regions 71a and 71b and the first base regions 61a and 61b and the conductor portion 12 can increase.

### Second Modification Example of First Embodiment

A SiC semiconductor device according to a second modification example of the first embodiment may contain 3H-SiC on an upper surface S4 (FIGS. 2 and 3) of the source regions 7a and 7b and the vicinity thereof. As illustrated in FIG. 3, a part of the upper surface S4 of the source regions 7a and 7b is not covered by the interlayer insulating film 13, and comes into direct contact with the source electrode 14 as illustrated in FIG. 2 to be electrically connected. By providing the 3C-SiC on the upper surface S4 of the source regions 7a and 7b and the vicinity thereof, the source regions 7a and 7b can be electrically connected to the source electrode 14 through both of the side surface and the upper surface S4 with a low resistance. When ions of the n-type impurity are implanted into the side surfaces S1 and S2 in the processes illustrated in FIGS. 8 and 9, ions of the n-type impurity are also implanted into the upper surface S4 of the source regions 7a and 7b such that the 3H-SiC forms the amorphous structure.

### Third Modification Example of First Embodiment

In the method of manufacturing the SiC semiconductor device according to the first embodiment, ions of the p-type impurity are implanted into the p-type semiconductor region, and ions of the n-type impurity are implanted into the n-type semiconductor region such that the structure of 4H-SiC collapses. The present technology is not limited to this configuration. In the method of manufacturing the SiC semiconductor device according to the third modification example of the first embodiment, to collapse the structure of 4H-SiC, ions of inert gas such as helium (He) or argon (Ar), silicon (Si), or carbon (C) are implanted into any one of the p-type semiconductor region and the n-type semiconductor region. Conditions such as the dose and the temperature for the ion implantation of the inert gas are the same as the conditions such as the dose and the temperature of the n-type impurity and the p-type impurity illustrated in FIGS. 5 to 9. The first source regions 71a and 71b, the first base regions 61a and 61b, and the first base contact region 51 formed as described above contain the inert gas element.

Ions of inert gas, silicon, or carbon are not likely to affect the conductivity type of the semiconductor. Therefore, ions of the same element can be implanted into any one of the p-type semiconductor region and the n-type semiconductor region. As a result, ions of different elements do not need to be implanted into the upper side and the lower side of the side surfaces S1 and S2 of the contact trench 11, and the process can be simplified.

### Other Embodiments

The first embodiment and the modification example thereof have been described. However, the description and the drawings forming a part of the disclosure are not intended to limit the present disclosure. It is obvious to those skilled in the art that various substitute embodiments, examples, and operation technology can be conceived from the present disclosure.

For example, the MOSFET has been described as the example of the semiconductor device according to the first embodiment and the modification example thereof. The present disclosure is also applicable to an insulated gate bipolar transistor (IGBT) having a configuration where a p⁺ type collector region is provided instead of the n⁺ type drain region 1. In addition to the single IGBT, the present disclosure is also applicable to a reverse-conducting IGBT (RC-IGBT) or a reverse-blocking insulated gate bipolar transistor (RB-IGBT).

In addition, when a metal material is deposited on the SiC semiconductor device, a barrier metal layer may be appropriately formed. By providing the barrier metal layer, adhesiveness between the metal material and the underlying layer can be improved, and diffusion of the metal material in the semiconductor can be suppressed.

In addition, an n-type high concentration layer may be provided on the upper surface side of the drift layer 2. The high concentration layer has higher impurity concentration than that of the drift layer 2, and a lower surface of the high concentration layer is in contact with the upper surface of the drift layer 2. The high concentration layer is, for example, a current spreading layer or an accumulation layer.

When the high concentration layer is provided, the lower surfaces of the base regions 6a and 6b are in contact with an upper surface of the high concentration layer. In addition, the gate trench 8 penetrates the source regions 7a and 7b and the base regions 6a and 6b and reaches the high concentration layer, and the high concentration layer is in contact with the side surface (side wall) of the gate trench 8. The gate bottom protection region 3 may be provided in the high concentration layer. In addition, the side surface of the base contact region 5 and the side surface and the lower surface of the buried region 4 may be in contact with the high concentration layer.

In addition, the configurations disclosed in the first embodiment and the modification examples can be appropriately combined within a range where no contradictions occur. This way, of course, the present disclosure includes various embodiments and the like not described herein. Accordingly, the technical scope of the present disclosure is only limited to the specific features of the invention according to the claims that are appropriate from the above description.

1. A silicon carbide semiconductor device comprising:
a semiconductor substrate containing silicon carbide;
an insulated gate electrode structure that is buried in a first trench provided in the semiconductor substrate;
a trench contact that is buried in a second trench provided in the semiconductor substrate;
a second conductivity type base region that is provided in contact with a side surface of the first trench and a side surface of the second trench in the semiconductor substrate;
a first conductivity type main electrode region that is provided in contact with the side surface of the first trench and the side surface of the second trench on an upper surface side of the base region; and
a second conductivity type base contact region that is provided in contact with a bottom surface of the second trench,
wherein a region along the side surface and the bottom surface of the second trench in the semiconductor substrate contains silicon carbide having a 3C structure.

2. The silicon carbide semiconductor device according to claim 1, wherein
a region along the side surface of the second trench in each of the base region and the main electrode region contains silicon carbide having a 3C structure, and
a region along the bottom surface of the second trench in the base contact region contains silicon carbide having a 3C structure.

3. The silicon carbide semiconductor device according to claim 1, wherein a cross-sectional shape of the second trench is rectangular or trapezoidal.

4. The silicon carbide semiconductor device according to claim 2, wherein
an impurity concentration in the region of the main electrode region is 1×10¹⁸ cm⁻³ or more and 7×10¹⁹ cm⁻³ or less, and
an impurity concentration in the region of the base region and an impurity concentration in the region of the base contact region are 1×10¹⁸ cm⁻³ or more and 2×10²⁰ cm⁻³ or less.

5. The silicon carbide semiconductor device according to claim 1, wherein the region along the side surface and the bottom surface of the second trench in the semiconductor substrate contains silicon carbide having a 3C structure and silicon carbide having a 4H structure.

6. The silicon carbide semiconductor device according to claim 2, wherein the region in each of the base region and the main electrode region and the region in the base contact region contains an inert gas element.

7. The silicon carbide semiconductor device according to claim 1, wherein the trench contact contains aluminum or tungsten.

8. The silicon carbide semiconductor device according to claim 1, wherein the silicon carbide having a 3C structure is formed through amorphization of silicon carbide having a 4H structure.

9. The silicon carbide semiconductor device according to claim 1, wherein an upper surface of the main electrode region contains silicon carbide having a 3C structure.

10. The silicon carbide semiconductor device according to claim 1, wherein
a plurality of the first trenches are provided, and
the second trench is provided between two of the first trenches adjacent to each other.
